(19) United States
(12) Patent Application Publication
(10) Pub. No.: US 2006/0261859 A1
(43) Pub. Date: Nov. 23, 2006

(54) Semiconductor integrated circuit device

(75) Inventor: Harumi Kawano, Miyazaki (JP)

Correspondence Address: NIXON PEABODY, LLP, 401 9TH STREET, NW, SUITE 900, WASHINGTON, DC, 20004-2128, US

(73) Assignee: Oki Electric Industry Co., Ltd., Tokyo (JP)

(21) Appl. No.: 11/434,886

(22) Filed: May 17, 2006

(30) Foreign Application Priority Data
May 17, 2005 (JP) 2005-143854

(51) Int. Cl. H03K 5/00; H03K 19/00; H03D 1/00; H01L 25/00

(52) U.S. Cl. 327/50; 326/101

(57) ABSTRACT

The purpose of the invention is providing a semiconductor circuit being able to supply either “L” level signal or “H” level signal to the subsequent stage logic circuit thereof.

The latch circuit 30 is placed between the output side of the analog circuit 10 and the input side of the logic circuit 20 and said latch circuit 30 is controlled by the power-down signal PD. And said power-down signal PD is changed to “H” level to set said analog circuit 10 into said operational mode and output the signal S10 having the requested logic level. While said signal S10 having the requested logic level is outputted, said power-down signal PD is changed to level “L”. Subsequently, the operation of said analog circuit 10 is halted and the signal S10 is stayed at level “L”, then the signal S10 of the analog circuit 10 being outputted shortly before the power-down signal PD becomes level “L”; is held by the latch circuit 30 and is provided to said logic circuit 20 as the signal 30.

### BACK GROUND OF THE INVENTION

### TECHNICAL FIELD OF THE INVENTION

The present invention relates to a technology for measuring consumption current during non-operational period of a semiconductor integrated circuit including analog circuits.

When a semiconductor integrated circuit is tested in production line, a non-operational-mode consumption current measuring test is conducted. In the non-operational-mode consumption current measuring test, the current is measured under the condition of deactivated circuits (non-operational state) in order to select good device or no-good device. Since typical semiconductor integrated circuits are not provided with clock signals, the current does not flow during the non-operational state with input signals having fixed high logic level (hereinafter referred to as level “H”) or low logic level (hereinafter referred to as level “L”). If the current flows, the cause must tomes from a defect of transistors or a short circuit of wiring thereof, then the device can be judged to be a no-good device.

### SUMMARY OF THE INVENTION

However, in the case of a semiconductor integrated circuit including analog circuits such as analog amplifiers or analog-digital converters, whether the device is good or not can not be judged only by the existence of the consumption circuit, because the consumption current flows in the analog circuits thereof even in the non-operational state. For the above reason, a circuit to make analog circuits thereof a power-down state during the non-operational mode consumption current measuring might be built in the circuit thereof.

FIG. 2 is a general configuration diagram of a conventional semiconductor integrated circuit including analog circuit. The semiconductor integrated circuit thereof includes a differential amplifier 10 on the input side and a logic circuit 20 conducting the digital processing based on an input signal S10 outputting from the differential amplifier 10.

The differential amplifier 10 includes N-channel transistors (hereinafter referred to as “NOMS”) 11,12 being provided with input signals IN1, IN2 into the gates thereof respectively, and the drains of NMOS 11,12 are connected the source voltage VDD through P-channel MOS transistors (hereinafter referred to as “PMOS”) 13,14. The gates of PMOS 13,14 are connected to the drain of NMOS 12.

The sources of NMOS 11,12 are connected to a drain of NMOS 15 and the source of NMOS 15 is connected to the ground voltage GND. The gate of NMOS 15 is configured to be given a power-down signal PD. Additionally, the drain of NMOS11 outputs a signal S10 being given to a logic circuit 20.

The non-operational-mode consumption-current measuring test in a production line of the above mentioned semiconductor circuit will be described as below.

In the probing test of semiconductor integrated circuit on wafer, the differential amplifier 10 and the logic circuit 20 are connected to the ground voltage VDD through ammeter respectively first, in order to measure the non-operational-mode consumption currents I10, I20 of the differential amplifier 10 and the logic circuit 20 separately.

Secondly, the power-down signal PD being given to the NMOS 15 of the differential amplifier 10 is set to level “L”. Consequently, the NMOS 15 is changed into the off-state, and the signal S10 is changed to level “H”. In the above state, the non-operational-mode consumption currents I10, I20 are measured to judge whether the measured value thereof is under the acceptable value, or not. If the measured value thereof is more than the acceptable value, the device under test is judged to be no-good one.

Patent document 1: Japanese Patent Journal H1-300829.

However, in the above semiconductor integrated circuit, when the diferntial amplifier 10 is changed into the power-down state by setting the level of power-down signal PD to level “L”, the output signal S10 from the differential amplifier 10 always remains at level “H”. Consequently, the non-operational-mode consumption current measuring test is done in the logic circuit 20, only when the input signal S10 is level “H”, and the non-operational-mode consumption current measuring cannot be done when signal level is set to level “L”. For the above reason, there is a problem that the defect thereof appearing only when the input signal has level “L” cannot be detected.

The object of present invention is to provide a semiconductor integrated circuit and the test method thereof being able to input one level out of level “L” or “H” into the subsequent stage logic circuits.

The present invention consists of an analog circuit, a latch circuit, and a logic circuit. The analog circuit outputs high logic level C or low logic level, corresponding to the input analog signal when the normal operation mode is set, and halts the operation outputting the fixed level “H” or “L” when the power-down mode is set. The latch circuit outputs directly the output from the above mentioned analog circuit when the normal operation mode is set, and holds and outputs the output signal being outputted from the analog circuit thereof shortly before the power-down mode is set when the power-down mode is set. The logic circuit conducts logic operations based on the output signals from the above mentioned latch circuit.

The present invention places the latch circuit between the analog circuit and logic circuit, and the latch circuit is configured to hold and output the output signal from the analog circuit thereof being outputted shortly before the power-down mode is set when the power-down mode is set; to the logic circuit thereof. Subsequently, during the power-down mode, any logic level out of level “H” or “L” can be provided into the logic circuit thereof, and then there is an effect that the non-operational mode consumption current measuring test can be done by inputting any logic level out of level “H” or “L”.

### BRIEF DESCRIPTION OF THE DRAWINGS

FIG. 1: a general configuration diagram of a semiconductor integrated circuit according to the first embodiment of the present invention.

FIG. 2: a general configuration diagram of a conventional semiconductor integrated circuit including analog circuits.

FIG. 3: a general configuration diagram of a semiconductor integrated circuit according to the second embodiment of the present invention.

### DETAILED DESCRIPTIOIN OF THE PREFERRED EMBODIMNETS

A delay circuit delaying the power-down signal setting the normal operation mode or the power-down mode by a given time and outputting the power-down signal; is built in for controlling the mode of analog circuit by the delayed power down signal. At the same time, the latch circuit is controlled by the not-delayed power down signal.

The above mentioned objects, other objects, and novel features of the present invention will become clearer by reading the following explanations of preferred embodiments referring to the attached drawings, however, the attached drawings are only for explanations and does not limit the scope of the present invention.

### FIRST EMBODIMENT

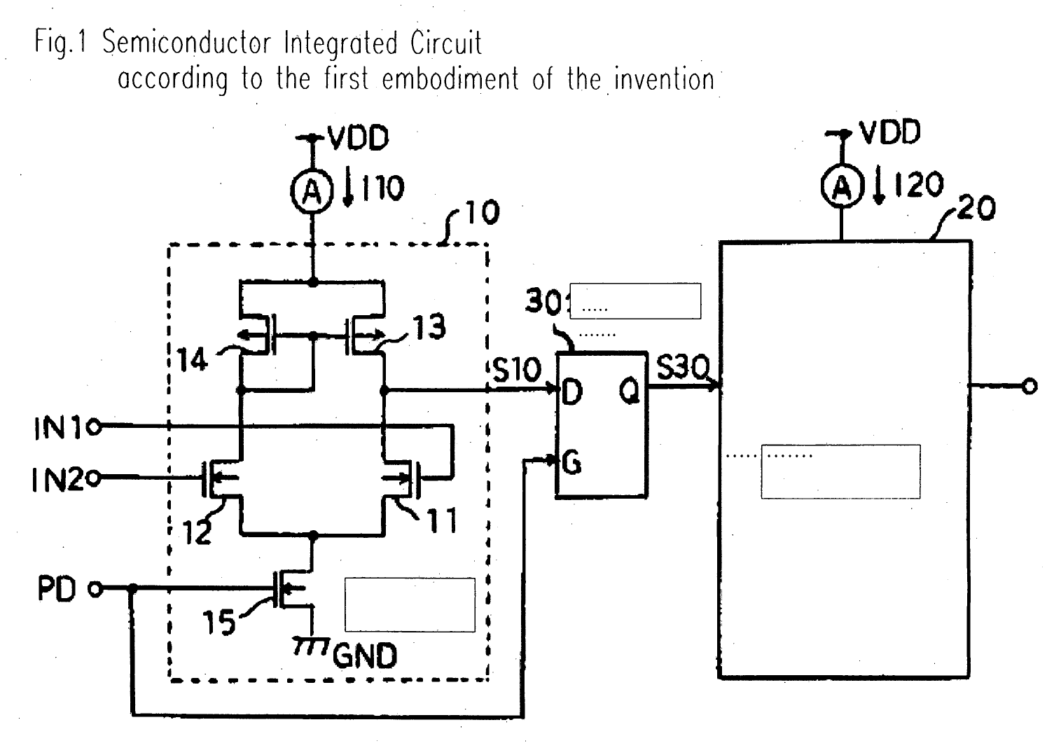

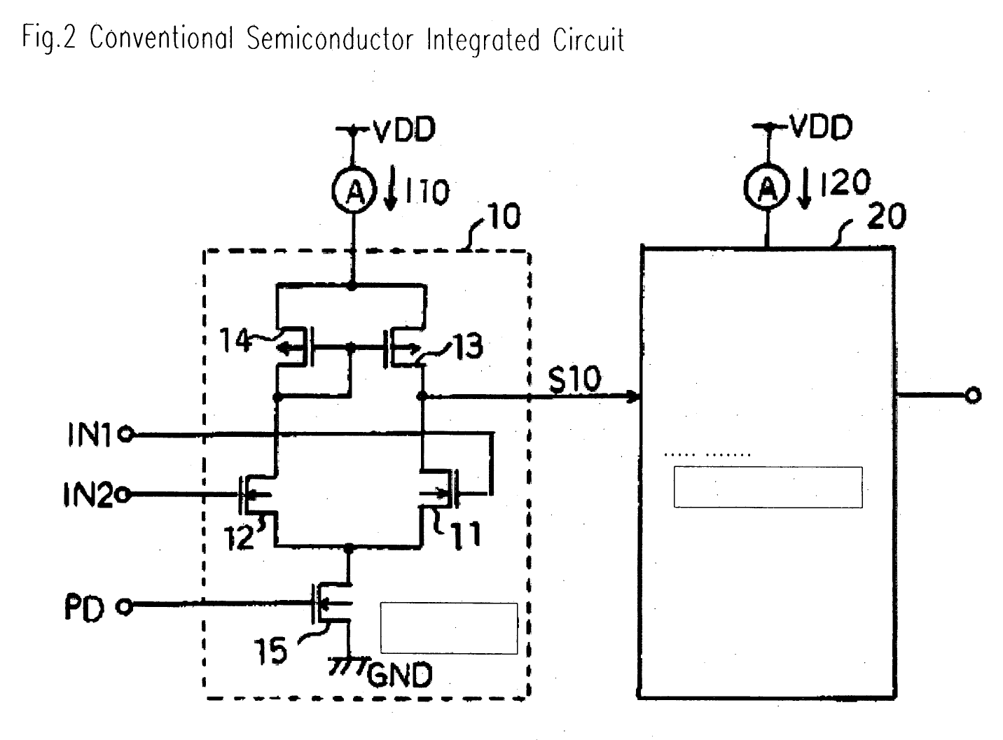

FIG. 1 is a general configuration diagram of a semiconductor integrated circuit according to the first embodiment of the present invention and the same numeral is given to an element identical to the one in FIG. 2.

The semiconductor integrated circuit includes the differential amplifier 10, the logic circuit 20, and the latch circuit 30.

The differential circuit 10 has the NMOS 11, 12 being inputted the input signals IN1, IN2 to the gates thereof respectively. The drains of NMOS 11, 12 are connected respectively to the ground voltage VDD through the PMOS 13, 14. The gates of PMOS 13, 14 are connected to the drain of the NMOS 12.

The sources of NMOS 11, 12 are connected to the drain of NMOS 15, and the source of the NMOS 15 is connected to the ground voltage GND. The gate of NMOS 15 is configured to be given the power-down signal PD. At the same time, the drain of NMOS 11 is configured to output the signal S1 to a data terminal D of the latch circuit 30.

The latch circuit 30 outputs directly the given input signal from the output terminal Q to the gate terminal G when the signal inputted to the gate terminal G is level “H”, and when the signal inputted to the gate terminal G is level “L”, the latch circuit 30 holds the output signal being outputted from the output terminal Q shortly before the signal inputted to the gate terminal G is level “L”, regardless of the input signal change.

The power-down signal PD is inputted to the gate terminal G of latch circuit 30, and the output signal S30 from the output terminal Q is given to the logic circuit 20.

An non-operational-mode consumption-current measuring test in the production line of the above mentioned semiconductor integrated circuit will be explained as below.

In the probing test of the wafer-process-stage semiconductor integrated circuit, the differential amplifier 10 and the logic circuit 20 are connected to the power supply voltage VDD through the ammeter respectively, in order to measure the non-operational-state consumption currents I10, I20 of the differential amplifier 10 and the logic circuit 20 separately.

First, the differential amplifier 10 is activated by setting the power-down signal PD given to the NMOS 15 thereof to level “H”, and the input signal IN1, IN2 setting the output signal S10 level to level “L” are given to differential amplifier 10. Subsequently, the signal S10 having level “L” is directly inputted to the logic circuit 20. In the above state, the power-down signal PD is changed to level “L”.

When the power-down signal PD is changed to level “L”, the NMOS 15 of the differential amplifier 10 becomes off-state. At the same time, the output signal of the latch circuit 30 is held level “L”, the level being set power-down signal PD is changed to level “L”. In the above stage, the non-operational-mode consumption currents I10, I20 are measured and checked whether the current values are less than the given acceptable value, or not. When the current value thereof exceeds the acceptable value, the device under test is judged to be no-good device.

Further, the differential amplifier 10 is activated by setting the power-down signal to level “H” again, and the input signals IN1, IN2 setting the output signal S10 from the differential amplifier 10 to level “H” are given to the differential amplifier 10 in turn. Subsequently, the signal S10 having level “H” is inputted directly to the logic circuit 20 as the signal S30. In the above state, the power-down signal PD is changed to level “L”.

When the power-down signal PD is changed to level “L”, the signal S10 becomes level “H”. At the same time, the signal S30 is held at the level “H”, the level being set shortly before the power-down signal PD is changed to level “L”. In the above state, the non-operational-mode consumption currents I10, I20 are measured and checked whether the current values are less than the given acceptable value, or not. When the current value thereof exceeds the acceptable value, the device under test is judged to be no-good device.

As explained before, the semiconductor integrated circuit according to the first embodiment of the present invention consists of the latch circuit 30 outputting the output signal S10 to the logic circuit 20 by latching the output signals S10 from the differential amplifier 10 by the power-down signal PD. Subsequently, even when the differential amplifier 10 is in the power-down state, since the signal given to the logic circuit 20 can be held at level being set shortly before the power-down state, there is an advantage of being able to conduct the non-operational consumption current measuring test in either state of level “H” or “L”.

Additionally, the present invention is not limited the above mentioned first embodiment, and can be applied to other embodiments being modified in many ways. Examples of the modified embodiments thereof are as follows.
(1) The differential amplifier 10 is taken as an example for the explanation of analog circuit being controlled into the power-down state by the power-down signal, however, other analog circuits (ex. analog digital converter) is applicable as the differential amplifier 10.
(2) In the logic circuit 20, the total non-operational-state consumption current is measured, however, the above logic circuit 20 can be configured to be divided into several blocks to measure each non-operational-state consumption current of every blocks thereof.
(3) The signal between the analog circuit and the digital circuit is not limited to one signal and is applicable to a plural of signals.

### SECOND EMBODIMENT

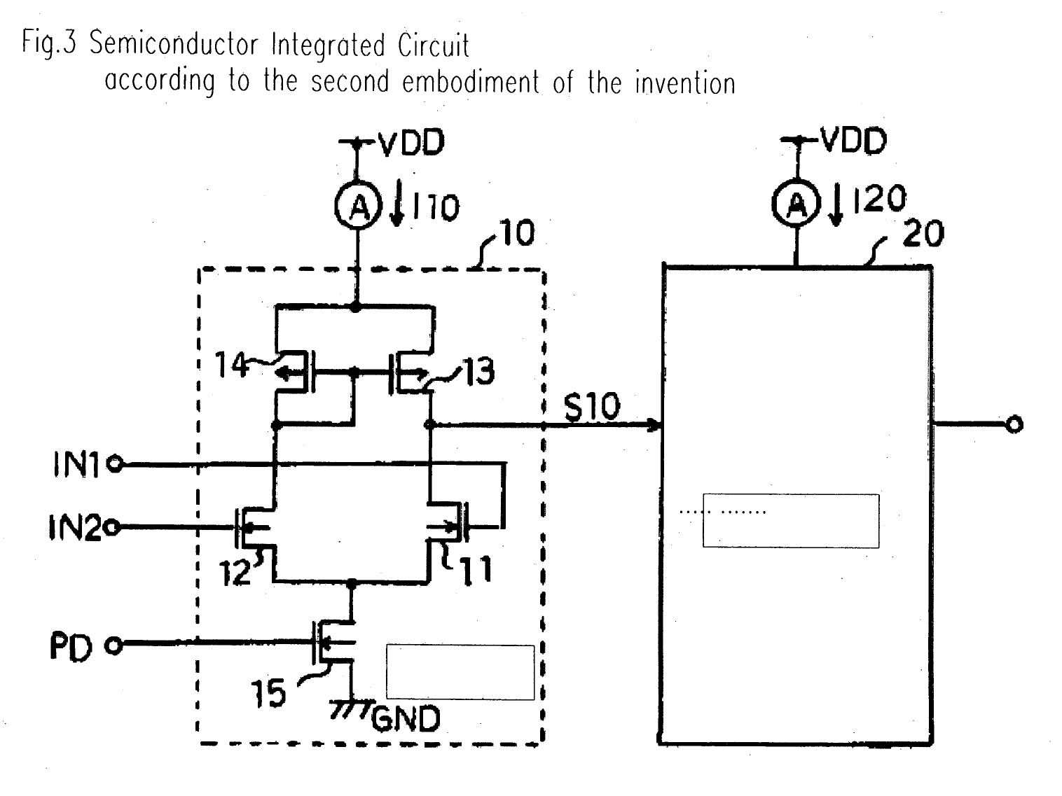

FIG. 3 is a general configuration diagram of the second embodiment of the present invention, and the same numeral is given an element identical to the one of FIG. 1.

The semiconductor integrated circuit includes the differential amplifier 10, the logic circuit 20, and the latch circuit 30, 31.

The differential amplifier 10, the logic circuit 20, the latch circuit 30 are the same as the ones of FIG. 1, except the different point that the signal inputted to the gate of NMOS 15 is the delayed power-down signal PDD, not the original power-down signal PD.

In the same way as the latch circuit 30, the latch circuit 31 outputs directly the input signal inputted to the data terminal D from the output terminal Q when the signal inputted to the gate terminal G has level “H”, and when the signal inputted to the gate terminal G changes to level “L”, the latch circuit 31 holds the output signal being outputted from the output terminal Q shortly before signal inputted to the gate terminal G is level “L”, regardless of any change of the input signal to the data terminal D.

The non-operational-state consumption-current measuring test in a production line of the above mentioned semiconductor circuit will be described as below.

In the probing test of the wafer-process-stage semiconductor integrated circuit, the differential amplifier 10 and the logic circuit 20 are connected to the power supply voltage VDD through the ammeter respectively, in order to measure the non-operational-state consumption currents I10, I20 of the differential amplifier 10 and the logic circuit 20 separately.

First, the power-down signal is set to level “H”, then the latch circuit 30 becomes through-state. At the same time, the gate terminal G of the latch circuit 31 is connected fixedly to the power supply voltage VDD, then the delayed power-down signal PDD becomes level “H” and the differential amplifier 10 is activated. Furthermore, the input signal IN1, IN2 setting the output signal S10 level to level “L” are given to differential amplifier 10. Subsequently, the signal S10 having level “L” is directly inputted to the logic circuit 20. In the above stage, the power-down signal PD is changed to level “L”.

When the power-down signal PD is changed to level “L”, the output signal S30 from the latch circuit 30 is held at the level “L”, the level being set shortly before the power-down signal PD is changed to level “L”. Furthermore, the power-down signal PD is delayed by the delay time of the latch circuit 31, and is inputted to the differential amplifier 10 as the delayed power-down signal PDD. Subsequently, the NMOS 15 of the differential amplifier 10 becomes off-state and the signal S10 is changed to level “H”. At the above time point, since the output signal S30 of the latch circuit 30 has been already held at level “L”, the signal S30 does not change. In the above state, the non-operational-mode consumption currents I10, I20 are measured and checked whether the current values are less than the given acceptable value, or not. When the current value thereof exceeds the acceptable value, the device under test is judged to be no-good device.

Further, the differential amplifier 10 is activated by setting the power-down signal to level “H” again, and the input signals IN1, IN2 setting the output signal S10 from the differential amplifier 10 to level “H” are given to the differential amplifier 10 in turn. Subsequently, the signal S10 having level “H” is inputted directly to the logic circuit 20 as the signal S30. In the above state, the power-down signal is changed to level “L”.

When the power-down signal PD is changed to level “L”, the delayed power-down signal PDD is changed to level “L”, and the signal S10 is changed to level “H”. At the same time, the signal S30 is held at level “H”, the level being set shortly before the power-down signal PD is changed to level “L”. In the above stage, the non-operational-mode consumption currents I10, I20 are measured and checked whether the current values are less than the given acceptable value, or not. When the current value thereof exceeds the acceptable value, the device under test is judged to be no-good device.

As explained before, the semiconductor integrated circuit according to the second embodiment includes the latch circuit 30 and the latch circuit 31. The latch circuit S30 latches the output signal S10 by the power-down signal PD and output the above latched output signal to the logic circuit 20. Furthermore, the latch circuit 31 delays the output signal S10 from the differential amplifier 10 by the given time so as to control the power down of differential amplifier 10. Subsequently, besides the same advantage as the first embodiment, the second embodiment of the present invention has another advantage of being able to conduct latching operation of the output signal S10 from the differential amplifier 10 by the latch circuit 30 at more accurate timing.

At the same time, the function of the latch circuit 31 is generation of the delayed power-down signal PDD only by delaying the power-down signal PD, then the latching function thereof is not indispensable. Consequently, the logic gates or delaying circuits composed by serially connected inverters, etc. are applicable thereto.

In the present application, no device claim is claimed. However, the following claims may be claimed in a separate application.

A test method of a semiconductor integrated circuit for measuring a non-operational state consumption current of said semiconductor integrated circuit including; an analog circuit being configured to output a fixed logic level corresponding to an analog input signal thereto during a normal operation mode and being configured to output a fixed logic level halting the operation thereof during a power-down mode; a latch circuit being connected to the output side of said analog circuit and being configured to output directly the output signal of said analog circuit during said normal mode and being configured to hold the output signal being outputted from said analog circuit shortly before the power-down mode and output said held output signal during said power-down mode; and a logic circuit conducting a logic operations based on the output signal from said latch circuit; said test method of a semiconductor integrated circuit comprising;
a first measuring process, wherein the current flowing in said analog circuit and said logic circuit is measured by setting said power-down mode while said analog circuit output the first logic level signal;
a second inputting process, wherein said normal mode is set and a input signal is inputted to output said second logic level signal;
a second measuring process, wherein currents flowing in said analog circuit and said logic circuit are measured by setting said power-down mode while said analog circuit outputs said second logic level; and
a judging process, wherein said semiconductor integrated circuit is judged to be good or no-good based on the current measured by said first measuring process and said second measuring process; wherein said first measuring process, said second inputting process, said second measuring process, and said judging process are processed sequentially.

What is claimed is:

1. A semiconductor integrated circuit comprising;
an analog circuit being configured to output high logic (referred to “H” hereinafter) level or low logic (referred to “L” hereinafter) level corresponding to an analog input signal thereto when a normal operation mode is set; and output fixed “H” or “L” level “H”alting the operation thereof when a power-down mode is set;
a latch circuit being connected to the output signal of said analog circuit and being configured to output the output directly signal from said analog circuit when a normal operation mode is set; and hold and output the output signal being outputted from said analog circuit shortly before said power-down mode is set when said power-down mode is set; and
a logic circuit conducting logic operation based on the output signal from said latch circuit.

2. A semiconductor integrated circuit comprising:
a delay circuit being configured to output a power-down signal for setting a normal operation mode or said power-down mode by delaying said power-down signal by a given period;
an analog circuit being configured to output “H” level or “L” level corresponding to an analog input signal thereto when a normal operation mode is set by said power-down signal; and halt the operation thereof and output fixed “H” or “L” level when said power-down mode is set by said power-down signal;
a latch circuit being connected to the output side of said analog circuit and being configured to output directly the output signal from said analog circuit when said normal operation mode is set by said power-down signal; and hold and output the output signal being outputted from said analog circuit shortly before said power-down mode is set when said power-down mode is set by said power-down signal; and
a logic circuit conducting logic operation based on the output signal from said latch circuit.
